(19) United States
(12) Patent Application Publication
(10) Pub. No.: US 2023/0069533 A1
(43) Pub. Date: Mar. 2, 2023

(54) PHOTORESIST REMOVAL METHOD AND PHOTORESIST REMOVAL DEVICE

(71) Applicant: CHANGXIN MEMORY TECHNOLOGIES, INC., Hefei City, Anhui (CN)

(72) Inventors: Ning XI, Hefei City, Anhui (CN); Wen GU, Hefei City, Anhui (CN)

(21) Appl. No.: 17/602,855

(22) PCT Filed: Jul. 9, 2021
(86) PCT No.: PCT/CN2021/105566

§ 371 Date: Oct. 11, 2021

(30) Foreign Application Priority Data
Nov. 9, 2020 (CN) 202011240233.0

(51) Int. Cl. G03F 7/42

(52) U.S. Cl. CPC G03F 7/42

(57) ABSTRACT

Embodiments of the present disclosure provide a photoresist removal method and a photoresist removal device. The photoresist removal method includes: providing a substrate and a photoresist located on the substrate; wherein the photoresist includes an inner core layer and an outer shell layer covering a surface of the inner core layer, and a concentration of ions doped in the outer shell layer is greater than a concentration of ions doped in the inner core layer; performing at least one shelling treatment on the photoresist, until the outer shell layer is completely removed; wherein one shelling treatment includes: performing a water vapor treatment on the outer shell layer to soften at least part of the outer shell layer, to form a soft outer shell layer; and removing the soft outer shell layer; and removing the inner core layer after the outer shell layer is completely removed.

### CROSS-REFERENCE TO RELATED APPLICATIONS

The present disclosure is a national stage of International Patent Application No. PCT/CN2021/105566, filed on Jul. 9, 2021, which claims the priority to Chinese Patent Application No. 202011240233.0, titled “PHOTORESIST REMOVAL METHOD AND PHOTORESIST REMOVAL DEVICE”, filed with China National Intellectual Property Administration (CNIPA) on Nov. 9, 2020. The entire contents of International Patent Application No. PCT/CN2021/105566 and Chinese Patent Application No. 202011240233.0 are incorporated herein by reference.

### TECHNICAL FIELD

The present disclosure relates to, but is not limited to, a photoresist removal method and a photoresist removal device.

### BACKGROUND

A photoresist is used as an anti-etching layer to protect a surface of a substrate. In design of a semiconductor device, considering a performance requirement of the device, ion implantation needs to be performed in a specific area to meet requirements of different functions of various devices. In order to meet such a requirement, a photoresist is usually coated on a substrate area that does not require the ion implantation, to prevent ions from being implanted into the substrate area and affecting performance of the semiconductor device. After the ion implantation, for the substrate coated with the photoresist, a hard shell of a particular thickness is formed on a surface of the photoresist, the interior of the shell is further wrapped with a photoresist without ion implantation, and the shell is mainly composed of linked compounds and doped ionic components.

The photoresist shell formed after ion implantation is relatively difficult to remove. In a photoresist removal process, an outer shell layer bulges or breaks, generating photoresist polymers that are difficult to remove, thus forming a large number of defects and affecting a yield of the semiconductor device. In summary, how to provide a photoresist removal method that can prevent a photoresist from bulging and breaking and generating photoresist polymer impurities is one of technical problems to be resolved urgently by those skilled in the art.

### SUMMARY

An overview of the subject matter detailed in the present disclosure is provided below, which is not intended to limit the protection scope of the claims.

A first aspect of the embodiments of the present disclosure provides a photoresist removal method. The photoresist removal method include: providing a substrate and a photoresist located on the substrate; wherein the photoresist includes an inner core layer and an outer shell layer covering a surface of the inner core layer, and a concentration of ions doped in the outer shell layer is greater than a concentration of ions doped in the inner core layer; performing at least one shelling treatment on the photoresist, until the outer shell layer is completely removed; wherein one shelling treatment includes: performing a water vapor treatment on the outer shell layer to soften at least part of the outer shell layer, to form a soft outer shell layer; and removing the soft outer shell layer; and removing the inner core layer after the outer shell layer is completely removed.

A second aspect of the embodiments of the present disclosure further provides a photoresist removal device. The photoresist removal device includes: a reaction chamber; a first pipeline, connected with the reaction chamber, and configured to provide water vapor into the reaction chamber; a second pipeline, connected with the reaction chamber, and configured to provide oxygen into the reaction chamber; and a plasma source device, wherein the plasma source device is configured to plasma-ionize a gas introduced into the reaction chamber.

### BRIEF DESCRIPTION OF THE DRAWINGS

The drawings incorporated into the specification and constituting a part of the specification illustrate the embodiments of the present disclosure, and are used together with the description to explain the principles of the embodiments of the present disclosure. In these drawings, similar reference numerals are used to represent similar elements. The drawings in the following descriptions are some rather than all of the embodiments of the present disclosure. Those skilled in the art may derive other drawings based on these drawings without creative efforts.

One or more embodiments are exemplified by corresponding accompanying drawings, and these exemplified descriptions do not constitute a limitation on the embodiments. Components with the same reference numerals in the accompanying drawings are denoted as similar components, and the accompanying drawings are not limited by scale unless otherwise specified.

FIG. 1 is a schematic structural diagram corresponding to a step of implanting ions into a photoresist located on a substrate in a photoresist removal method;

FIG. 2 is a schematic structural diagram corresponding to a step of removing an outer shell layer by using a gas mixture in a photoresist removal method;

FIG. 3 is a schematic structural diagram of generating photoresist polymer impurities in a photoresist removal method;

FIG. 4 is a schematic structural diagram corresponding to a step of removing an inner core layer by using oxygen and nitrogen in a photoresist removal method;

FIG. 5 is a schematic structural diagram of a substrate and a photoresist in a photoresist removal method according to an embodiment of the present disclosure;

FIG. 6 is a schematic structural diagram corresponding to a step of introducing water vapor to form a soft outer shell layer in a photoresist removal method according to an embodiment of the present disclosure;

FIG. 7 is a schematic structural diagram corresponding to a step of removing a soft outer shell layer in a photoresist removal method according to an embodiment of the present disclosure;

FIG. 8 is a schematic structural diagram corresponding to a step of converting a remaining outer shell layer into a soft outer shell layer in a photoresist removal method according to an embodiment of the present disclosure;

FIG. 9 is a schematic structural diagram corresponding to a step of removing a soft outer shell layer formed in a second water vapor treatment in a photoresist removal method according to an embodiment of the present disclosure;

FIG. 10 is a schematic structural diagram corresponding to a step of removing an inner core layer in a photoresist removal method according to an embodiment of the present disclosure; and

FIG. 11 is a schematic structural diagram of a photoresist removal device according to an embodiment of the present disclosure.

### DETAILED DESCRIPTION

As can be learned from the background, in the prior art, removal of a photoresist on which ions have been implanted is prone to generate polymer impurities that are difficult to remove, and an outer shell layer has a high hardness due to a high concentration of doped ions and is prone to bulge and break due to high temperature in a photoresist removal process, generating polymer impurities that are difficult to remove, and thus causing a large number of defects, making the removal process imperfect and affecting a yield of a semiconductor device.

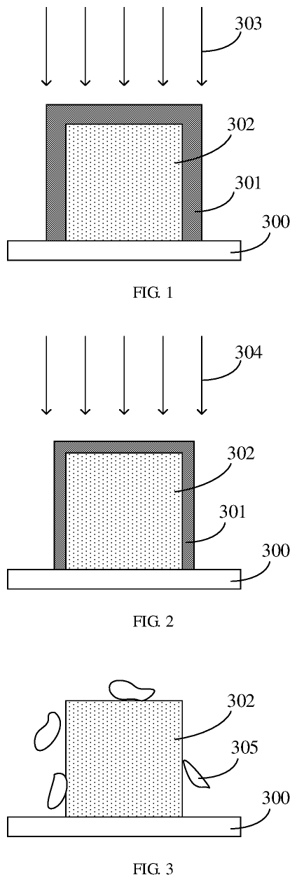

FIG. 1 to FIG. 4 are each a schematic structural diagram corresponding to steps in a photoresist removal method.

Referring to FIG. 1, ions 303 are implanted into a photoresist located on a substrate 300, so that the photoresist forms an outer shell layer 301 and an inner core layer 302. In a semiconductor device, ion implantation needs to be performed on a specific area to enable the semiconductor device to meet various function requirements. Usually, the photoresist is coated on an area of the substrate 300 that does not require the ion implantation to prevent ions from being implanted into the substrate 300 in the area.

Referring to FIG. 2 and FIG. 3, the outer shell layer 301 is removed by using a gas mixture 304 of hydrogen and nitrogen. The hydrogen reacts with the photoresist into which the ions 303 are implanted, to remove the outer shell layer 301. However, the outer shell layer 301 of the photoresist has a high hardness due to the implantation of a large number of ions and is prone to bulge and break during the reaction to generate photoresist polymer impurities 305. Such photoresist polymer impurities 305 are easily splashed onto various areas on the substrate 300 and are difficult to remove during subsequent removal of the inner core layer 302, resulting in a large number of defects on the substrate 300, and causing a yield of the semiconductor device to decrease.

Referring to FIG. 4, the inner core layer 302 is removed by using oxygen and nitrogen, and the removal process is a combustion reaction.

During the foregoing photoresist removal process, a large number of polymer impurities that are difficult to remove are easily generated on the substrate, resulting in a large number of defects, and affecting a yield of the semiconductor device.

An embodiment of the present disclosure provides a photoresist removal method, which softens an outer shell layer by using water vapor before removing the outer shell layer, thereby helping resolve a problem of causing a large number of defects by polymers generated due to photoresist bulging and breaking during photoresist removal.

The embodiments of the present disclosure are described in detail below with reference to the accompanying drawings. However, those skilled in the art can understand that many technical details are proposed in the embodiments of the present disclosure to help readers better understand the present disclosure. However, even without these technical details and various changes and modifications made based on the following embodiments, the technical solutions claimed in the present disclosure can still be realized.

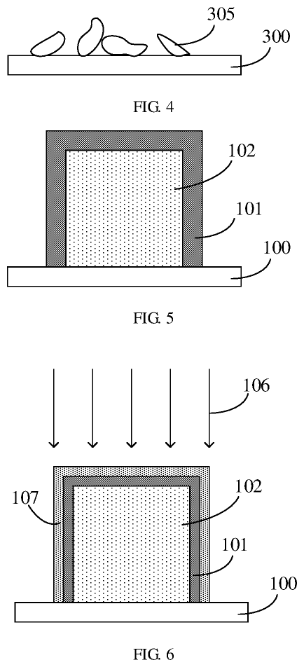

FIG. 5 to FIG. 10 are each a schematic structural diagram corresponding to steps in a photoresist removal method according to a first embodiment of the present disclosure.

Referring to FIG. 5, a substrate 100 and a photoresist located on the substrate 100 are provided. The photoresist includes an inner core layer 102 and an outer shell layer 101 covering a surface of the inner core layer 102. The concentration of ions doped in the outer shell layer 101 is greater than the concentration of ions doped in the inner core layer 102.

In this embodiment, the substrate 100 is a semiconductor a substrate, and may be a silicon substrate, a germanium substrate, a silicon germanium substrate, a silicon substrate on insulator, or the like. In other embodiments, alternatively, the substrate may include a semiconductor substrate and a transistor structure, bit line structure or word line structure located in the substrate.

The photoresist is used as a mask for performing an ion implantation process on the substrate 100 and serves to locate an area for ion implantation. Implanted ions in the ion implantation process may be N-type ions or P-type ions. The N-type ions include arsenic ions and phosphorus ions. The P-type ions include fluoride ions and boron ions. Alternatively, the implanted ions in the ion implantation process may be other appropriate ions, so as to meet a performance requirement to be met by the ion implantation process.

The photoresist is exposed in an environment of the ion implantation process, so that the implanted ions in the ion implantation process are also implanted into the photoresist, and a shorter distance to a center area of the photoresist indicates a smaller ion concentration. Therefore, after the ion implantation process, the photoresist includes the inner core layer 102 and the outer shell layer 101, and the concentration of ions doped in the outer shell layer 101 is greater than the concentration of ions doped in the inner core layer 102. In addition, a hardness of the outer shell layer 101 is usually greater than that of the inner core layer 102.

Subsequent process steps include: performing at least one shelling treatment on the photoresist, until the outer shell layer 101 is removed. In this embodiment, only a case of completely removing the outer shell layer 101 by two shelling treatments is described. In other embodiments, the outer shell layer may be completely removed by one shelling treatment, or the outer shell layer may be completely removed by more than two shelling treatments. That the outer shell layer 101 is completely removed by two shelling treatments in this embodiment is described in detail below with reference to the accompanying drawings.

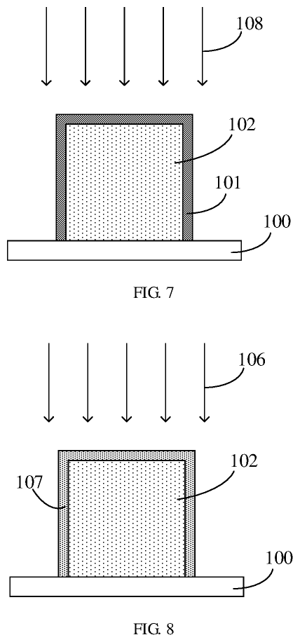

Referring to FIG. 6, one shelling treatment includes: introducing water vapor 106 to perform a water vapor treatment on the outer shell layer 101 to soften part of the outer shell layer 101, to form a soft outer shell layer 107.

The water vapor 106 is introduced into the outer shell layer 101 of the photoresist for the water vapor treatment, to soften part of the outer shell layer 101 to form the soft outer shell layer 107, and the formed soft outer shell layer 107 is removed. The foregoing process is repeated to remove the remaining outer shell layer 101. The inner core layer 102 is removed after the outer shell layer 101 is completely removed. Part of the outer shell layer 101 is softened by using the water vapor 106 first, and a hardness of the part of the outer shell layer 101 decreases. In a subsequent removal process, the outer shell layer 101 no longer bulges or breaks due to an extremely high hardness, and the soft outer shell layer 107 is completely removed cleanly, thereby resolving a problem of causing a large number of defects by polymer impurities generated due to photoresist bulging and breaking in the photoresist removal process, and improving the photoresist removal process.

If the outer shell layer 101 is not to be softened, the outer shell layer 101 has a high hardness due to a high concentration of doped ions and is prone to bulge and break due to the extremely high hardness in the photoresist removal process, generating polymer impurities that are difficult to remove.

In this embodiment, the water vapor treatment includes: providing water vapor 106 to the outer shell layer 101, so as to soften at least part of the outer shell layer 101; where the temperature of the water vapor is not less than 100° C. A smaller difference between the temperature of the water vapor 106 and a deformation temperature of the outer shell layer 101 indicates a better effect of softening the outer shell layer 101 by the water vapor treatment. A lower hardness of the formed soft outer shell layer 107 indicates a smaller probability that the outer shell layer 101 bulges and breaks in the subsequent removal process.

A flow rate of the water vapor provided in the softening treatment is 2000 mg per minute to 10000 mg per minute, and may be 4000 mg per minute, 6000 mg per minute, or 8000 mg per minute. The flow rate of the water vapor determines a speed at which the outer shell layer 101 is softened.

Process parameters of the softening treatment include: process duration of 30 seconds to 300 seconds, which may be 100 seconds, 180 seconds, or 250 seconds; and a reaction chamber temperature of 100° C. to 120° C., which may be 105° C., 110° C., or 115° C.

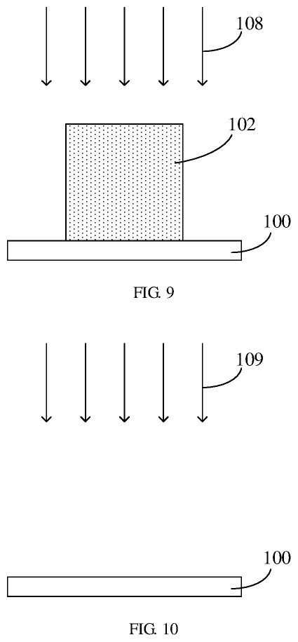

The soft outer shell layer 107 (referring to FIG. 6) is removed after part of the outer shell layer 101 is softened. Due to its low hardness, the soft outer shell layer 107 does not bulge or break due to a high hardness during removal, and can be removed gently and cleanly, referring to FIG. 7.

Referring to FIG. 7, a method of removing the soft outer shell layer 107 includes: providing a hydrogen-containing plasma 108 to the photoresist, to etch the soft outer shell layer 107. The hydrogen-containing plasma 108 reacts with doped ions (arsenic ions, phosphorus ions, fluoride ions, boron ions, or the like), to generate polyhydride by-products, the polyhydride by-products are discharged out of the reaction chamber, and the outer shell layer 101 is removed.

During the removal of the soft outer shell layer 107, a carrier gas further needs to be introduced into the reaction chamber. The carrier gas includes argon or nitrogen.

In this embodiment, a method of forming the hydrogen-containing plasma 108 includes: providing water vapor to the photoresist, and performing a first plasma treatment on the water vapor, to form the hydrogen-containing plasma 108. A flow rate of the water vapor used in the first plasma treatment is 2000 mg per minute to 10000 mg per minute, and may be 4000 mg per minute, 6000 mg per minute, or 8000 mg per minute. In this way, there is no need to provide other gases to the reaction chamber, and the softened outer shell layer 107 can be removed by using the water vapor 106 in the softening treatment, thereby simplifying process steps. In other embodiments, alternatively, hydrogen may be provided to the reaction chamber, and the provided hydrogen may be plasma-ionized to form the hydrogen-containing plasma.

Process parameters for removing the soft outer shell layer 107 include: process duration of 1 minute to 10 minutes, which may be 4 minutes, 6 minutes, or 8 minutes; and a reaction chamber temperature of 100° C. to 120° C., which may be 105° C., 110° C., or 115° C.

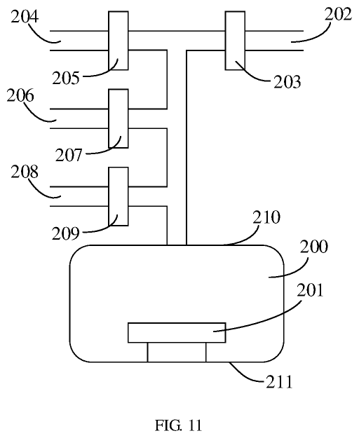

Referring to FIG. 8 and FIG. 9, when the outer shell layer 101 has a high thickness, and the outer shell layer 101 cannot be completely removed by one shelling treatment, a second shelling treatment is performed on the outer shell layer 101 to completely remove the outer shell layer 101.

Referring to FIG. 8, the water vapor 106 is introduced into the remaining outer shell layer 101 (referring to FIG. 7) after the first shelling treatment for the water vapor treatment, and the remaining outer shell layer 101 is completely converted into the soft outer shell layer 107.

Referring to FIG. 9, the hydrogen-containing plasma 108 is provided to the soft outer shell layer 107 (referring to FIG. 8), the soft outer shell layer 107 formed in the second water vapor treatment is removed, and the inner core layer 102 is removed after the outer shell layer 101 is completely removed.

Referring to FIG. 10, the inner core layer 102 (referring to FIG. 9) is removed after the outer shell layer 101 is removed.

In an example, a method of removing the inner core layer 102 includes: providing an oxygen-containing plasma 109 to the inner core layer 102, where the oxygen-containing plasma 109 reacts with the inner core layer 102 to generate carbon dioxide, carbon monoxide, and water.

During the removal of the inner core layer 102, a carrier gas further needs to be introduced into the reaction chamber. The carrier gas includes argon or nitrogen.

In this embodiment, a method of forming the oxygen-containing plasma 109 includes: providing oxygen to the inner core layer 102, and performing a second plasma treatment on the oxygen, to form the oxygen-containing plasma 109. A gas flow rate of the oxygen used in the second plasma treatment is 1000 standard milliliters per minute to 15000 standard milliliters per minute, and may be 5000 standard milliliters per minute, 10000 standard milliliters per minute, or 12000 standard milliliters per minute. The oxygen-containing plasma 109 formed by performing second plasma-ionization with oxygen reacts quickly with the inner core layer 102, so that the inner core layer can be quickly removed, thereby improving photoresist removal efficiency.

In other embodiments, a method of forming the oxygen-containing plasma further includes: providing water vapor to the inner core layer, and performing a third plasma treatment on the water vapor, to form the oxygen-containing plasma. A flow rate of the water vapor used in the third plasma treatment is 2000 mg per minute to 10000 mg per minute, and may be 4000 mg per minute, 6000 mg per minute, or 8000 mg per minute. In the formation of the oxygen-containing plasma achieved by performing the third plasma treatment on the water vapor, there is no need to provide the reaction chamber with any new gas, and the inner core layer can be removed by using the softening treatment and the water vapor obtained after the removal of the outer shell layer on which the softening treatment has been performed, thereby simplifying the process steps.

In the entire photoresist removal process, water vapor can be used for the softening treatment, the removal of the softened outer shell layer, and the removal of the inner core layer. However, water vapor at different stages have different gas flow rates and durations for providing the water vapor are also different.

In this embodiment, the shelling treatment and the removal of the inner core layer are performed in a same reaction chamber. In this way, the entire photoresist removal process is performed in the same reaction chamber, thereby avoiding a risk of contamination of the photoresist by an external environment when different chambers are used in different steps, simplifying the process environment, and making the entire removal process easier to achieve. In other embodiments, the shelling treatment for photoresist removal and the removal of the inner core layer may be performed in different reaction chambers.

This embodiment provides a photoresist removal method, a water vapor treatment is performed on an outer shell layer of a photoresist first to form a soft outer shell layer, and then the soft outer shell layer and an inner core layer are sequentially removed, where a hardness of the soft outer shell layer decreases, so that the outer shell layer can be gently removed without bulging or breaking during removal, thereby resolving a problem of causing a large number of defects by a large number of polymer impurities generated during photoresist removal, and improving a yield of a semiconductor device.

A second embodiment of the present disclosure provides a photoresist removal device. The photoresist removal device provided in this embodiment is described in detail below with reference to the accompanying drawings.

FIG. 11 is a schematic structural diagram of a photoresist removal device according to the second embodiment of the present disclosure.

Referring to FIG. 11, in this embodiment, the photoresist removal device includes: a reaction chamber 200; a first pipeline 202, connected with a reaction chamber 200, and configured to provide water vapor into the reaction chamber 200; a second pipeline 204, connected with the reaction chamber 200, and configured to provide oxygen into the reaction chamber 200; and a plasma source device (not shown), where the plasma source device is configured to plasma-ionize a gas introduced into the reaction chamber 200.

The photoresist removal device includes the first pipeline 202 that provides water vapor into the reaction chamber 200, ensuring that water vapor can be provided to a photoresist when the device performs a photoresist removal process. In addition, the water vapor softens an outer shell layer of the photoresist, thereby ensuring that the photoresist does not bulge or break, and resolving a problem of causing a large number of defects by polymer impurities generated due to photoresist bulging and breaking during photoresist removal.

In this embodiment, the reaction chamber 200 includes a base 201, and the base 201 is configured to accommodate a substrate containing the photoresist.

The plasma source device may include a top electrode plate 210 and a bottom electrode plate 211. The top electrode plate 210 and the bottom electrode plate 211 are located on two opposite sides of the reaction chamber 200, and are configured to plasma-ionize a gas introduced into the reaction chamber 200.

The first pipeline 202 is configured to provide water vapor into the reaction chamber 200, so that the water vapor softens the outer shell layer of the photoresist, thereby reducing a hardness of the outer shell layer, and ensuring that the photoresist does not bulge or break during subsequent removal.

The photoresist removal device may further include a first flow control device 203. The first flow control device 203 is disposed on the first pipeline 202 and is configured to control a flow rate of the water vapor introduced into the reaction chamber 200 by the first pipeline 202.

In this embodiment, the first flow control device 203 may be a liquid flow controller (LFC). The LFC can quickly and accurately measure a volume flow/mass flow rate of a liquid flowing by, and use a high-speed proportional control valve to accurately control the volume flow/mass flow rate of the liquid. In other embodiments, the first flow control device may be a mass flow controller (MFC). The MFC directly measures a mass flow rate of a medium passing, and may further measure density of the medium and indirectly measure temperature of the medium.

The second pipeline 204 is configured to provide oxygen into the reaction chamber 200. Providing oxygen can speed up the removal of the inner core layer of the photoresist, thereby helping improve photoresist removal efficiency.

The photoresist removal device may further include a second flow control device 205. The second flow control device 205 is disposed on the second pipeline 204 and is configured to control a flow rate of the oxygen introduced into the reaction chamber 200 by the second pipeline 204.

In this embodiment, the second flow control device 205 is an MFC.

The photoresist removal device may further include: a third pipeline 206, where the third pipeline 206 is connected with the reaction chamber 200 and is configured to introduce a first carrier gas into the reaction chamber 200; and a fourth pipeline 208, where the fourth pipeline 208 is connected with the reaction chamber 200 and is configured to introduce a second carrier gas into the reaction chamber 200.

The first carrier gas may be argon, and the second carrier gas may be nitrogen. In other embodiments, the first carrier gas is nitrogen, and the second carrier gas is argon. Nitrogen and argon are inert gases. The inert gases do not react with the photoresist and do not affect the photoresist removal process, but can carry water vapor and oxygen into the reaction chamber to ensure a gas inlet speed. In addition, reaction by-products of the shelling treatment and the removal of the inner core layer can be discharged out of the reaction chamber by introducing argon and nitrogen.

The photoresist removal device may further include: a third flow control device 207, where the third flow control device 207 is disposed on the third pipeline 206 and is configured to control a flow rate of the first carrier gas introduced into the reaction chamber 200 by the third pipeline 206; and a fourth flow control device 209, where the fourth flow control device 209 is disposed on the fourth pipeline 208 and is configured to control a flow rate of the second carrier gas introduced into the reaction chamber 200 by the fourth pipeline 208.

The third flow control device 207 and the fourth flow control device 209 are both MFCs.

In other embodiments, alternatively, the photoresist removal device may include a fifth pipeline and a fifth flow rate control device disposed on the fifth pipeline. The fifth pipeline is configured to provide hydrogen into the reaction chamber, and the hydrogen is plasma-ionized to form a hydrogen-containing plasma, for removal of the softened outer shell layer of the photoresist. The fifth flow rate control device is configured to control a gas flow rate of the hydrogen introduced into the reaction chamber by the fifth pipeline. The fifth flow rate control device may be an MFC.

The photoresist removal device may further include a sixth pipeline. The sixth pipeline is connected with the reaction chamber 200. The sixth pipeline is configured to discharge reaction by-products in the reaction chamber 200 out of the reaction chamber 200.

The photoresist removal device may further include a water tank and a control device. The water tank is connected with the first pipeline 202 and is configured to provide water vapor to the first pipeline 202. The control device is connected with the water tank and is configured to control temperature of the water vapor in the water tank to be greater than 100° C.

The photoresist removal device provided in this embodiment includes the first pipeline that provides water vapor into the reaction chamber, ensuring that water vapor can be provided to the photoresist when the device performs a photoresist removal process. In addition, the water vapor softens an outer shell layer of the photoresist, thereby ensuring that the photoresist does not bulge or break, and resolving a problem of causing a large number of defects by polymer impurities generated due to photoresist bulging and breaking during photoresist removal.

In the descriptions of this specification, a description with reference to terms such as “an embodiment”, “an exemplary embodiment”, “some implementations”, “an exemplary implementation” and “an example” means that the specific feature, structure, material or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the descriptions of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figure. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

The photoresist removal method and the photoresist removal device provided in the embodiments of the present disclosure ensure that water vapor can be provided to a photoresist when a photoresist removal process is performed, and the water vapor softens an outer shell layer of the photoresist, so that the photoresist does not bulge or break, thereby resolving a problem of causing a large number of defects by a large number of polymer impurities generated during photoresist removal, and improving a yield of a semiconductor device.

1. A photoresist removal method, comprising:
providing a substrate and a photoresist located on the substrate; wherein the photoresist comprises an inner core layer and an outer shell layer covering a surface of the inner core layer, and a concentration of ions doped in the outer shell layer is greater than a concentration of ions doped in the inner core layer;
performing at least one shelling treatment on the photoresist, until the outer shell layer is completely removed; wherein one shelling treatment comprises: performing a water vapor treatment on the outer shell layer to soften at least part of the outer shell layer, to form a soft outer shell layer; and removing the soft outer shell layer; and
removing the inner core layer after the outer shell layer is completely removed.

2. The photoresist removal method according to claim 1, wherein the water vapor treatment comprises: providing water vapor to the outer shell layer, so as to soften at least part of the outer shell layer; wherein a temperature of the water vapor is not less than 100° C.

3. The photoresist removal method according to claim 1, wherein the step of removing the soft outer shell layer comprises: providing a hydrogen-containing plasma to the photoresist, to etch the soft outer shell layer.

4. The photoresist removal method according to claim 3, wherein the step of forming the hydrogen-containing plasma comprises: providing water vapor to the photoresist, and performing a first plasma treatment on the water vapor, to form the hydrogen-containing plasma.

5. The photoresist removal method according to claim 1, wherein the step of removing the inner core layer comprises: providing an oxygen-containing plasma to the inner core layer, the oxygen-containing plasma reacts with the inner core layer.

6. The photoresist removal method according to claim 5, wherein the step of forming the oxygen-containing plasma comprises: providing oxygen to the inner core layer, and performing a second plasma treatment on the oxygen, to form the oxygen-containing plasma.

7. The photoresist removal method according to claim 1, wherein the shelling treatment and the removal of the inner core layer are performed in a same reaction chamber.

8. A photoresist removal device, comprising:
a reaction chamber;
a first pipeline, connected with the reaction chamber, and configured to provide water vapor into the reaction chamber;
a second pipeline, connected with the reaction chamber, and configured to provide oxygen into the reaction chamber; and
a plasma source device, wherein the plasma source device is configured to plasma-ionize a gas introduced into the reaction chamber.

9. The photoresist removal device according to claim 8, wherein the photoresist removal device further comprises a first flow control device; the first flow control device is disposed on the first pipeline and is configured to control a flow rate of the water vapor introduced into the reaction chamber by the first pipeline.

10. The photoresist removal device according to claim 8, wherein the photoresist removal device further comprises a second flow control device; the second flow control device is disposed on the second pipeline and is configured to control a flow rate of the oxygen introduced into the reaction chamber by the second pipeline.

11. The photoresist removal device according to claim 8, wherein the photoresist removal device further comprises a third pipeline and a fourth pipeline; the third pipeline is connected with the reaction chamber and is configured to introduce a first carrier gas into the reaction chamber; the fourth pipeline is connected with the reaction chamber and is configured to introduce a second carrier gas into the reaction chamber.

12. The photoresist removal device according to claim 11, wherein the photoresist removal device further comprises a third flow control device and a fourth flow control device; the third flow control device is disposed on the third pipeline and is configured to control a flow rate of the first carrier gas introduced into the reaction chamber by the third pipeline; the fourth flow control device is disposed on the fourth pipeline and is configured to control a flow rate of the second carrier gas introduced into the reaction chamber by the fourth pipeline.

13. The photoresist removal method according to claim 2, wherein a flow rate of the water vapor provided in the water vapor treatment is 2000 mg per minute to 10000 mg per minute, and a process duration of the water vapor treatment is 30 seconds to 300 seconds.

14. The photoresist removal method according to claim 4, wherein, during at least one of removing the soft outer shell layer or removing the inner core layer, a carrier gas is introduced into a reaction chamber, the carrier gas comprises argon or nitrogen.

15. The photoresist removal method according to claim 4, wherein a flow rate of the water vapor used in the first plasma treatment is 2000 mg per minute to 10000 mg per minute.

16. The photoresist removal method according to claim 6, wherein a gas flow rate of the oxygen used in the second plasma treatment is 1000 standard milliliters per minute to 15000 standard milliliters per minute.

17. The photoresist removal method according to claim 5, wherein the step of forming the oxygen-containing plasma comprises: providing water vapor to the inner core layer, and performing a third plasma treatment on the water vapor, to form the oxygen-containing plasma; and a flow rate of the water vapor used in the third plasma treatment is 2000 mg per minute to 10000 mg per minute.

18. The photoresist removal device according to claim 8, wherein the plasma source device comprises a top electrode plate and a bottom electrode plate; the top electrode plate and the bottom electrode plate are located on two opposite sides of the reaction chamber, and are configured to plasma-ionize a gas introduced into the reaction chamber.

19. The photoresist removal device according to claim 8, wherein the photoresist removal device further comprises a fifth pipeline and a fifth flow rate control device arranged on the fifth pipeline; the fifth pipeline is configured to provide hydrogen into the reaction chamber, and the hydrogen is plasma-ionized to form a hydrogen-containing plasma, for removal of a softened outer shell layer of a photoresist; the fifth flow rate control device is configured to control a gas flow rate of the hydrogen introduced into the reaction chamber by the fifth pipeline.

20. The photoresist removal device according to claim 8, wherein the photoresist removal device further comprises a sixth pipeline; the sixth pipeline is connected with the reaction chamber, and the sixth pipeline is configured to discharge reaction by-products in the reaction chamber out of the reaction chamber.
